(19) United States
(12) Patent Application Publication
(10) Pub. No.: US 2018/0254322 A1
(43) Pub. Date: Sep. 6, 2018

(54) FORMING NANOSHEET TRANSISTORS WITH DIFFERING CHARACTERISTICS

(71) Applicant: International Business Machines Corporation, Armonk, NY (US)

(72) Inventors: Kangguo Cheng, Schenectady, NY (US); Xin Miao, Guilderland, NY (US); Wenyu Xu, Albany, NY (US); Chen Zhang, Guilderland, NY (US)

(21) Appl. No.: 15/970,085

(22) Filed: May 3, 2018

Related U.S. Application Data
(62) Division of application No. 15/252,844, filed on Aug. 31, 2016.

(51) Int. Cl. H01L 29/06; H01L 29/66; H01L 21/3065; H01L 21/28; H01L 29/786; H01L 21/308

(52) U.S. Cl. CPC H01L 29/0665; H01L 29/66545; H01L 21/3065; H01L 21/308; H01L 21/28044; H01L 29/78696

(57) ABSTRACT

A method of forming a transistor in an integrated circuit device can include forming a first and second nanosheet structure with alternating sheets of silicon and silicon germanium. A first and second transistor structure are constructed using the first and second nanosheet structures as first and second channels. The sheets of silicon germanium are removed from the first and second nanosheet structures. A mask is placed over the first transistor structure, leaving the second transistor structure exposed. The second channel is thinned while the first transistor is protected by the mask. Thereafter, semiconductor processing continues, with the first transistor having a thicker channel than the second transistor.

### CROSS-REFERENCE TO RELATED APPLICATION

This application is a division of U.S. application Ser. No. 15/252,844, filed Aug. 31, 2016, the contents of which are hereby incorporated by reference in its entirety.

### BACKGROUND

The present invention relates in general to integrated circuit device structures and their fabrication. More specifically, the present invention relates to the fabrication of transistors with varying characteristics in integrated circuit devices.

Integrated circuit devices are a set of electronic circuits on one small chip of semiconductor material. A typical integrated circuit device includes many transistors. Sometime, chip designers wish to have transistors with different characteristics. For example, there can be a desire for a “wimpy” transistor, also known as a transistor with a “wimpy” gate. Such a transistor can have a higher threshold voltage than other (also known as “nominal”) transistors in an integrated circuit. While it can be desirable to create transistors with differing characteristics in a single integrated circuit device, such a process is much easier in an integrated circuit using planar transistor technology. In an integrated circuit using FinFET or nanosheet technology, making transistors with such varying characteristics can be difficult.

### SUMMARY

Embodiments herein are directed to a method of forming a structure of a semiconductor device. The method includes forming a first and second nanosheet structure including alternating sheets of silicon and silicon germanium. A first transistor structure is formed using the first nanosheet structure as a first channel. A second transistor structure is formed using the second nanosheet structure as a second channel. The sheets of silicon germanium are removed from the first and second nanosheet structures. A mask is placed over the first transistor structure, leaving the second transistor structure exposed. The second channel is thinned. The creation of the first transistor structure and the second transistor structure is finalized.

Embodiments described herein are also directed to an integrated circuit device that includes a first transistor and a second transistor. The integrated circuit device is formed by forming a first and second nanosheet structure including alternating sheets of silicon and silicon germanium. A first transistor structure is formed using the first nanosheet structure as a first channel. A second transistor structure is formed using the second nanosheet structure as a second channel. The sheets of silicon germanium are removed from the first and second nanosheet structures. A mask is placed over the first transistor structure, leaving the second transistor structure exposed. The second channel is thinned. The creation of the first transistor and the second transistor is finalized.

Additional features are realized through the techniques of the present invention. Other embodiments are described in detail herein and are considered a part of the claimed invention. For a better understanding of the invention with the features, refer to the description and to the drawings.

### BRIEF DESCRIPTION OF THE DRAWINGS

The subject matter which is regarded as the invention is particularly pointed out and distinctly claimed in the claims at the conclusion of the specification. The forgoing features are apparent from the following detailed description taken in conjunction with the accompanying drawings in which:

FIG. 1 depicts a side view of an exemplary initial structure;

FIG. 2 depicts the structure after the gate has been removed;

FIG. 3 depicts the structure after the removal of the SiGe layers;

FIG. 4 depicts the structure after the placement of a mask over a nominal transistor and the thinning of the channels of the wimpy transistor;

FIG. 5 depicts a final structure of the illustrated transistors; and

FIG. 6 depicts a flow diagram illustrating a methodology according to one or more embodiments.

### DETAILED DESCRIPTION

It is understood in advance that although a detailed description of an exemplary transistor configuration is provided, implementation of the teachings recited herein are not limited to the particular structure described herein. Rather, embodiments of the present invention are capable of being implemented in conjunction with any other type of integrated circuit device, now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well-known and so, in the interest of brevity, many conventional steps will only be mentioned briefly herein or will be omitted entirely without providing the well-known process details.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the terms “invention” or “present invention” are non-limiting terms and not intended to refer to any single aspect of the particular invention but encompass all possible aspects as described in the specification and the claims.

Described herein is a method of forming transistors with differing gate structures in a single integrated circuit device. As semiconductor feature sizes become smaller, conventional methods of forming transistors with differing gate structures in an integrated circuit becomes impractical.

Turning now to an overview of the present invention, one or more embodiments form transistors with a different gate dimensions from other transistors in the integrated circuit device, allowing a single integrated circuit device to have transistors with different gate structures, such that transistors can have different operating characteristics. Among the differing operating characteristics can be the threshold voltage. In particular, a “wimpy” transistor is a transistor with a higher threshold voltage than a nominal transistor. The higher threshold voltage can lead to a smaller leakage current for the wimpy transistor compared to a nominal transistor and lower power consumption. While a wimpy transistor will not have performance that matches the nominal transistor, wimpy transistors can be used to for less critical functions of an integrated circuit. Thus, an integrated circuit designer can find it desirable to have both nominal transistors and wimpy transistors in the integrated circuit device. In an integrated circuit that uses nanosheet technology in the channel, creating wimpy transistors using traditional techniques can be problematic. It has been found that using a thinner channel can create a wimpy transistor. For example, if a nominal transistor has a thickness of 10 nm, a wimpy transistor with a 5.5 nm channel will have a 30 mV (0.03 V) higher threshold voltage.

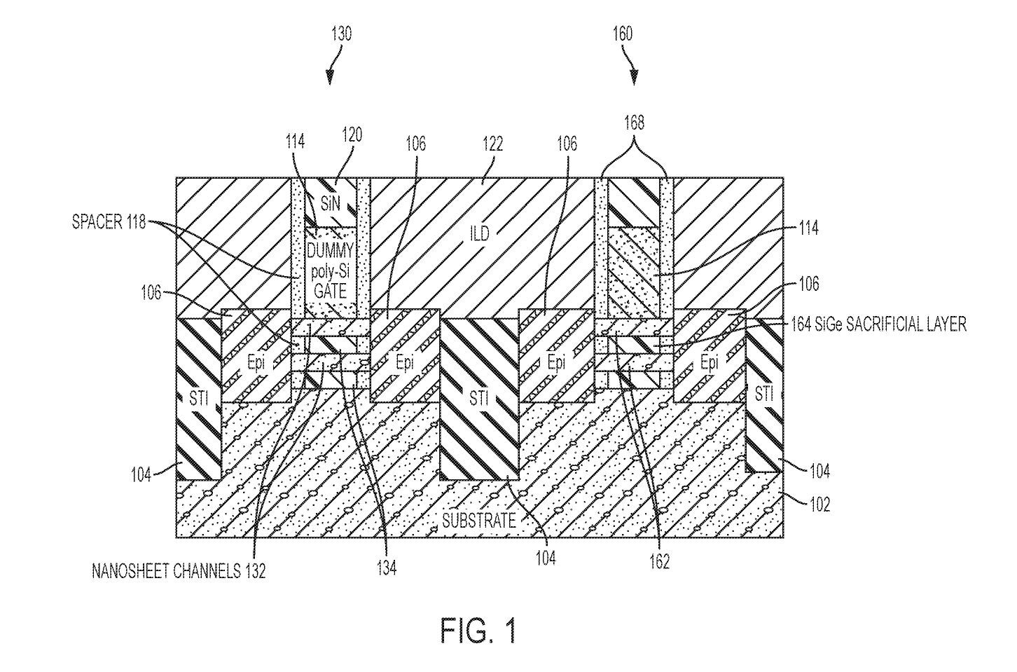

Turning now to a more detailed description of an embodiment of the present invention, a preliminary fabrication methodology for forming transistors with differing characteristics in accordance with one or more embodiments will now be described with reference to FIGS. 1 through 6.

Referring now to FIG. 1, an initial structure with two transistors, 130 and 160. These transistors 130 and 160 will be formed on a single substrate 102. At this point in the formation of the transistors, a standard nanosheet transistor formation process has taken place up to the formation of the dummy gate.

Each of transistor 130 and 160 have identical structures at this point. Transistor 130 includes shallow trench isolation regions 104 above substrate 102, epitaxial regions 106, 108, 110, and 112, a dummy gate (typically made of polysilicon) 114, a spacer 118, a nitride 120, and an inter-layer dielectric 122. Below dummy gate 114 are a series of nanosheet channels 132. Separating the nanosheet channel layers are a series of SiGe sacrificial layers 134. In future steps, transistor 130 will become a “nominal” transistor, or a transistor with the default channel thickness.

Transistor 160 includes shallow trench isolation regions 104 above substrate 102, epitaxial regions 106, 108, 110, and 112, a dummy gate (typically made of polysilicon) 114, a spacer 168, a nitride 120, and an inter-layer dielectric 122. Below dummy gate 114 are a series of nanosheet channels 162. Separating the nanosheet channel layers are a series of SiGe sacrificial layers 164. At this point in the process, nanosheet channel 132 of transistor 130 and nanosheet channel 162 of transistor 160 are identical. In future steps, transistor 160 will become a “wimpy” transistor, or a transistor with a smaller channel thickness.

While only two devices, transistor 130 and transistor 160, are shown in these drawing figures, it should be understood that a typical integrated circuit device will contain millions of transistors, some of which will have a traditional or conventional construction, and some of which will have a “wimpy” construction.

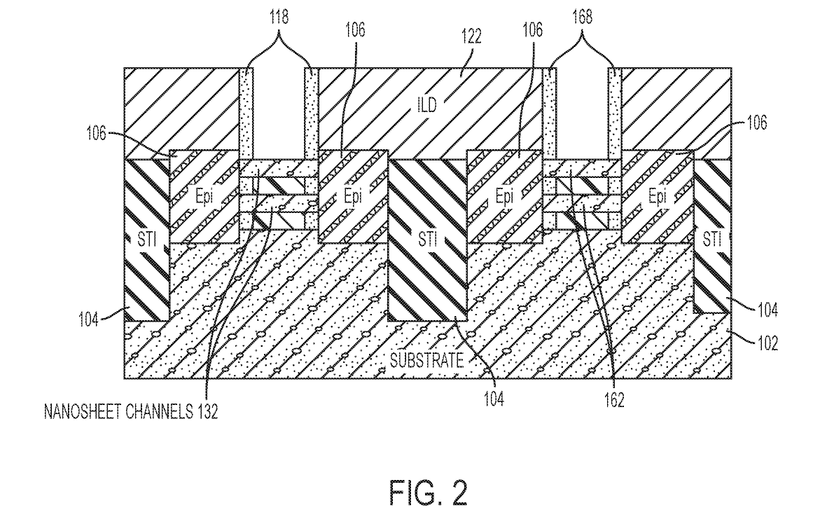

A poly-open chemical mechanical polish (CMP) is performed to remove nitride 120 without affecting the remainder of the structures. Thereafter, the polysilicon gate 114 can be removed by an etch, such as a reactive ion etch (ME). The result is illustrated in FIG. 2. Atop substrate 102 are shallow trench isolation 104, epitaxial regions 106, 108, 110, and 112, spacer 118, and inter-layer dielectric 122. There are a series of nanosheet channels 132 and 162. Separating the nanosheet channel layers are a series of SiGe layers 134 and 164. These can be referred to as sacrificial layers. At this point in the process, nanosheet channel 132 of transistor 130 and nanosheet channel 162 of transistor 160 remain identical.

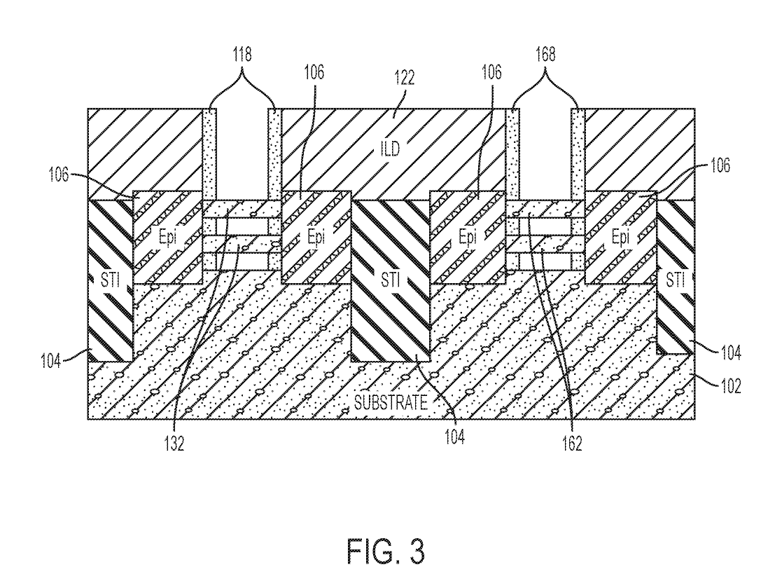

Thereafter, the SiGe sacrificial layers 134 and 164 are removed, resulting in the structure of FIG. 3. This removal can be accomplished in one of a variety of different manners known in the art. In some embodiments, a selective etch can be performed for the removal. The etch can be a reactive ion etch (ME), a gaseous etch, or a wet etch, as long as it is selective to the SiGe layers.

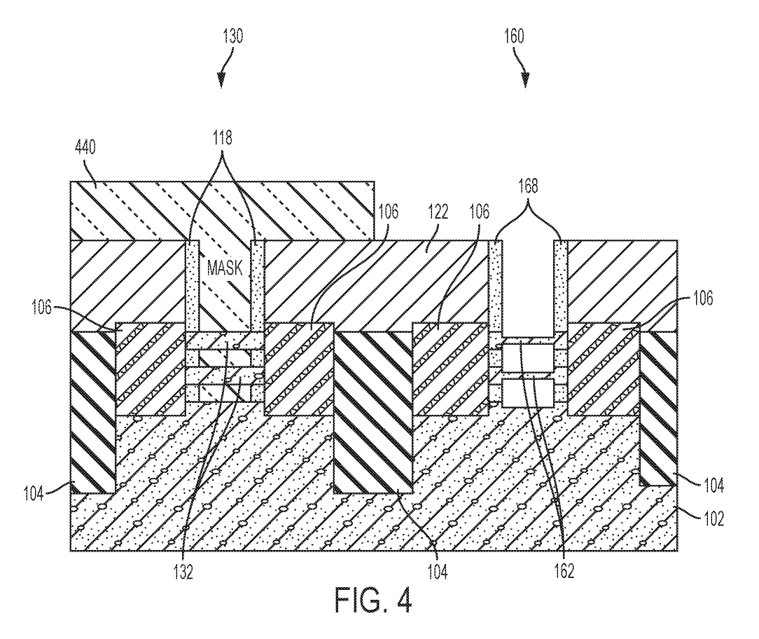

Thereafter, a mask 440 is placed over transistor 130, resulting in the structure illustrated in FIG. 4, with transistor 130 having an overlying mask 130 and transistor 160 being exposed. The mask 440 is used to protect the nominal transistors from the following steps. Mask 440 can be one of a variety of different materials. In some embodiments, mask 400 is a nitride, such as a silicon nitride.

Thereafter, operations can be performed on the “wimpy” transistor 160. The nanosheet channels 162 can be thinned in one of a variety of different methods. In some embodiments, to ensure control over the thinning process, a combination of oxidation and followed by etching using hydrofluoric acid can be performed such to perform the thinning of nanosheet channels 162. Other methods, such as atomic layer etching, also can be used. In some embodiments, an oxide etching that is specifically directed towards materials that have been oxidized. Quantum mechanical effects of the thinner nanosheet channel result in the transistor 160 having a higher threshold voltage Vₜ. Such acts have no effect on transistor 130 because the presence of mask 400 prevents the above-described steps from affecting transistor 130.

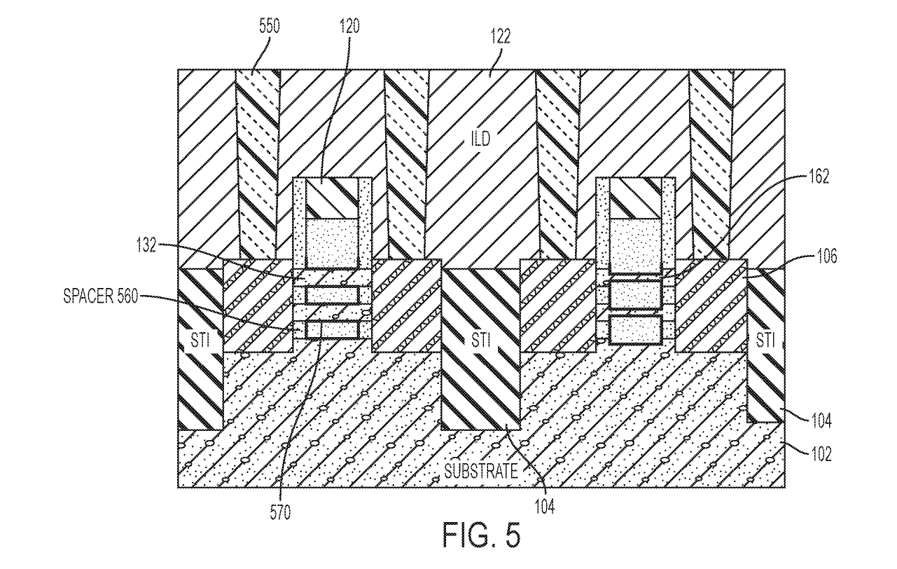

Thereafter, mask 400 is removed. Thereafter, conventional processing steps can be performed on both transistor 130 and wimpy transistor 160. Processing steps can include the placement of high-K dielectrics, a metal gate, and contacts for the source and drain areas. A simplified version of the resulting structure can be as shown in FIG. 5.

As shown in FIG. 5, there are contacts 550 coupled to each of the source/drain epitaxial regions. In addition, there is a spacer 560 between each of the device channels on both transistor 130 and wimpy transistor 160. A high-k dielectric 570 can also be present. In some embodiments, the high-k dielectric is formed from hafnium oxide. Other features also can be present, but are not illustrated in FIG. 5.

As described above, thinning a channel from 10 nm to 5-6 nm can result in a change in threshold voltage of 30 mV. In some embodiments, such a change can be all that is used. An advantage of limiting the thinning is that process control variations can be too difficult to control if more material is removed from the channel. However, it should be understood that other levels of thinning, both those resulting in thicker or thinner channels (down to approximately 3 nm or even lower), can be used.

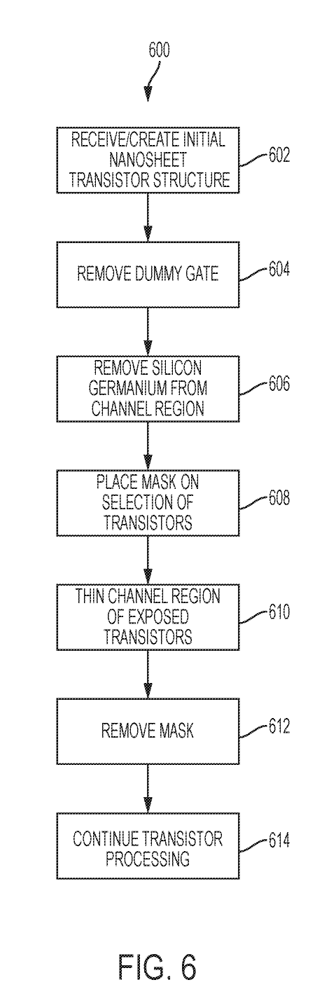

FIG. 6 is a flow diagram illustrating a methodology 600 according to one or more embodiments. At block 602, a nanosheet transistor including alternating sheets of epitaxially deposited silicon and epitaxially deposited silicon germanium is provided or created. The transistor includes at least two transistors. A typical structure will include a substrate. On the substrate are epitaxial regions that will later form the source and drain areas. Also present is a nanosheet channel region, with a dummy gate region atop the nanosheet channel region. At block 604, a chemical-mechanical polish (CMP) or similar procedure is performed to remove the dummy gate structure. At block 606, layers of silicon germanium are removed from the nanosheet channel region. This can be performed in one of a variety of different manners known in the art. At block 608, a mask is placed over some of the transistors. The transistors covered by the mask will be protected from subsequent processing steps. At block 610, operations are performed on the transistors that are not covered by the mask (the “exposed” transistors). In some embodiments, a combination of oxidation of the channel layers followed by an etching can be performed that serve to thin the channel layers. Such a thinning of the channel layers results in a rise of the threshold voltage of the transistor. At block 612, the mask is removed. Thereafter, at block 614, conventional processing steps can be performed on both normal transistors and “wimpy” transistors to complete the fabrication of the transistors on the integrated circuit device.

Thus, it can be seen from the forgoing detailed description and accompanying illustrations that embodiments of the present invention provide structures and methodologies for providing transistors with differing operating characteristics, such as different threshold voltages.

The descriptions of the various embodiments of the present invention have been presented for purposes of illustration, but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form described herein. Many modifications and variations will be apparent to those of ordinary skill in the art without departing from the scope and spirit of the invention. The embodiment was chosen and described in order to best explain the principles of the inventive teachings and the practical application, and to enable others of ordinary skill in the art to understand the invention for various embodiments with various modifications as are suited to the particular use contemplated.

The diagrams depicted herein are just one example. There can be many variations to this diagram or the operations described therein without departing from the spirit of the invention. For instance, the operations can be performed in a differing order or operations can be added, deleted or modified. All of these variations are considered a part of the claimed invention.

While various embodiments have been described, it will be understood that those skilled in the art, both now and in the future, can make various modifications which fall within the scope of the claims which follow. These claims should be construed to maintain the proper protection for the invention first described.

What is claimed is:

1. A method of forming gate structures of a first transistor and a second transistor in an integrated circuit device, the method comprising:
forming a first and a second nanosheet structure each comprising alternating sheets of silicon and silicon germanium;
forming the first transistor structure, using the first nanosheet structure as a first channel of the first transistor;
forming the second transistor structure, using the second nanosheet structure as a second channel of the second transistor;
removing the sheets of silicon germanium from the first and second nanosheet structures;
placing a mask over the first transistor structure, leaving the second transistor structure exposed; and
reducing a thickness dimension of the second nanosheet structure using an atomic layer etching process to thin the second channel without affecting the first channel.

2. The method of claim 1 wherein thinning the second channel comprises:
removing approximately 40 to 50 percent of a thickness of the second channel.

3. The method of claim 2 wherein thinning the second channel comprises:
reducing the thickness of the second channel from approximately 10 nanometers to approximately 5 to 6 nanometers.

4. The method of claim 2 wherein thinning the second channel comprises:
reducing the thickness of the second channel to approximately 3 nanometers.

5. The method of claim 1 wherein thinning the second channel raises a threshold voltage of the second transistor.

6. The method of claim 5 wherein the threshold voltage of the second transistor is raised by approximately 0.03 volts compared to a threshold voltage of the first transistor.

7. The method of claim 1 wherein:
removing the sheets of silicon germanium comprises using a selective etch process.

8. The method of claim 1 wherein:
the first transistor structure and second transistor structure each include a polysilicon gate assembly beneath a nitride hard mask.

9. The method of claim 8 further comprising:
performing a chemical mechanical polish to remove the nitride hard mask; and
performing an etch to remove the polysilicon gate assembly.

10. The method of claim 9 wherein:
the etch comprises a reactive ion etch.

11. The method of forming an integrated circuit device, the method comprising:
forming a first nanosheet transistor having a first channel thickness; and
forming a second nanosheet transistor having a second channel thickness;
wherein the first channel thickness is greater than the second channel thickness.

12. The method of claim 11, wherein the second nanosheet transistor comprises one or more silicon nanosheet channels.

13. The method of claim 11, wherein:
the first channel thickness is approximately 10 nanometers; and
the second channel thickness is approximately 5 to 6 nanometers.

14. The method of claim 11, wherein:
the first channel thickness is approximately 10 nanometers; and
the second channel thickness is approximately 3 nanometers.

15. The method of claim 11, wherein:
the first nanosheet transistor has a first threshold voltage;
the second nanosheet transistor has a second threshold voltage; and
the second threshold voltage is greater than the first threshold voltage.

16. The method of claim 15, wherein:
the first threshold voltage is approximately 30 millivolts greater than the second threshold voltage.

17. The method of claim 11, wherein:
the first nanosheet transistor comprises one or more silicon nanosheet channels.

18. The method of claim 17, wherein the first nanosheet transistor further comprises a spacer formed between each of the one or more silicon nanosheet channels.

19. The method of claim 17, wherein the first nanosheet transistor further comprises a high-k dielectric formed between each of the one or more silicon nanosheet channels.

20. The method of claim 11 further comprising:
forming a shallow trench isolation layer in the substrate between the first nanosheet transistor and the second nanosheet transistor.
